(19) United States
(12) Patent Application Publication
(10) Pub. No.: US 2004/0028165 A1
(43) Pub. Date: Feb. 12, 2004

(54) Digital phase detector with extended resolution

(76) Inventor: Wladyslaw Bogdan, Ottawa (CA)

Correspondence Address: Wladyslaw Bogdan, 1210 Major Str., Ottawa, ON, K2C 2S2, CA

(21) Appl. No.: 10/437,335

(22) Filed: May 2, 2003

Related U.S. Application Data
(62) Division of application No. 09/664,756, filed on Sep. 19, 2000.
(60) Provisional application No. 60/154,827, filed on Sep. 20, 1999.

(51) Int. Cl. H03D 3/24

(52) U.S. Cl. 375/375

(57) ABSTRACT

An inexpensive digital phase detector with extended resolution for digital signal processing and for timing circuits for wireless, optical or wireline transmission systems.

In particular this invention allows using size limited clock counters for measurements of unlimited time ranges by combining unlimited number of intermediate samples without accumulating samples granularity errors.

In addition to the measurements of the final time ranges, the intermediate samples are available for purposes of digital signal processing.

### BACKGROUND OF THE INVENTION

1. Field of the Invention

This invention is directed to providing high resolution low cost digital phase detectors which can be used: in digital phase locked loops (DPLLs), in other digital signal processing circuits, and shall also make possible other replacements of analog circuits by their digital implementations.

The digital phase detectors with extended resolution can be used for a wide range of data rates, and for wireless, optical, or wireline transmission and communication systems.

2. Background Art

Most of currently used digital phase detectors have resolution limited by a clock cycle time.

While some most advanced digital phase detectors allow higher resolutions which may be comparable with propagation delays of clock propagating gates, they have other limitations such as complex algorithms which are required for eliminating dependency of their phase resolution on technological process and power supply variations.

There is a need for digital phase detectors, which have simpler algorithms and greater independence versus the propagation delays of the detector control circuits and the clock propagating gates.

### SUMMARY OF THE INVENTION

Purpose of the invention It is an object of present invention to create new digital phase detection techniques, which simplify currently known phase detectors logic and control algorithms of output clock phase, while improving performances of known solutions like the direct digital frequency synthesis (DDFS).

Digital Phase Detector with Extended Resolution

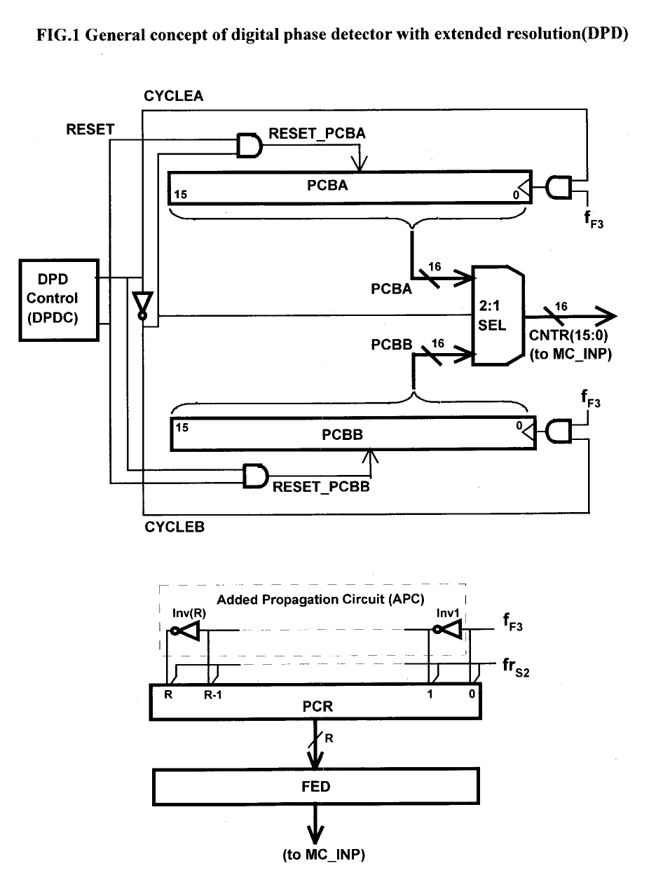

The invention also includes a new concept of a digital phase detector with extended resolution (DPD) which is shown in FIG. 1.

The DPD uses two symmetrical phase counters buffers A/B (PCBA/PCBB), which perform reverse functions during alternative A/B cycles of the frame clock fr_{S2} which is derived from the synchronized clock f_{S2}. During the A cycle, the PCBA counts the number of incoming f_{F3} clocks, but during the following B cycle the PCBA remains frozen until its content is read by the MC and subsequently the PCBA is reset before the beginning of the next A cycle. Alternatively, the PCBB performs counting during the B cycle and is read and reset during the following A cycle.

Such symmetrical PCBA/PCBB configuration allows much more time for counters propagation by inhibiting counting long before actual reading takes place. Therefore, much higher frequencies of counted clocks are allowed for the same IC technology. Generally speaking the above new concept of a digital phase detector, represents one of several possible DPD solutions; which are based on counting a first signal clock during every second signal frame, wherein the second signal frame contains a fixed number of the second signal clocks.

For all said DPD solutions, the invention further includes improving a DPD resolution by introducing a phase capture register. The phase capture register captures a state of outputs of multiple serially connected gates which the first signal clock is continuously propagated through, at the leading edge of the second signal frame. Such resolution improvement is implemented in the DPD1, by using the phase capture register (PCR) to measure positioning of a last fr_{S2} edge versus f_{F3} waveform. The PCR and its frame edge decoder (FED), improve phase detection resolution by 10 times versus conventional methods.

Said improvement of a DPD resolution further comprises two different solutions for obtaining the first clock propagation functionality:

adding the first clock propagation circuit specifically for providing input for the phase capture register; or utilizing a first clock propagation circuit which already inherently exists in a system and is used by the system for other purposes as well.

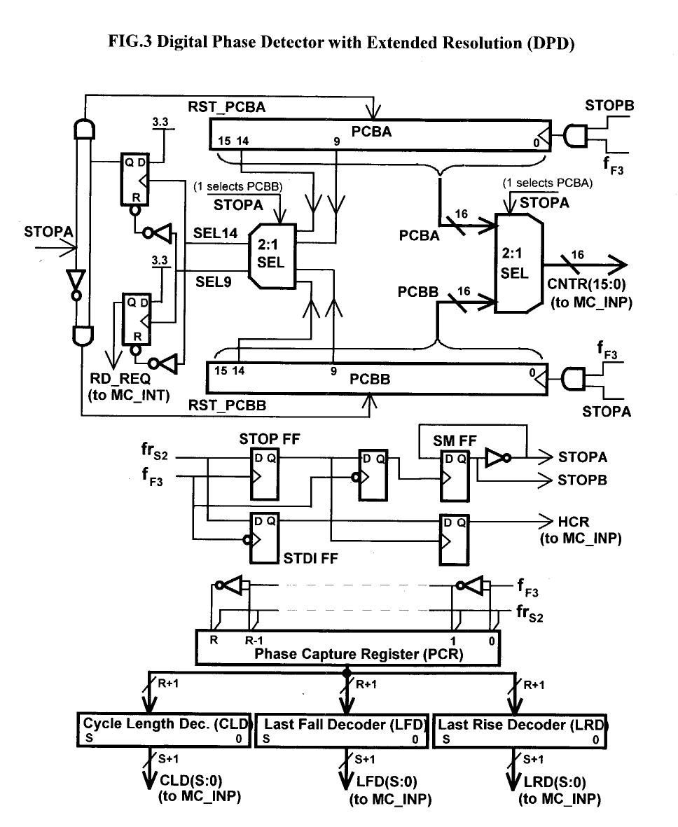

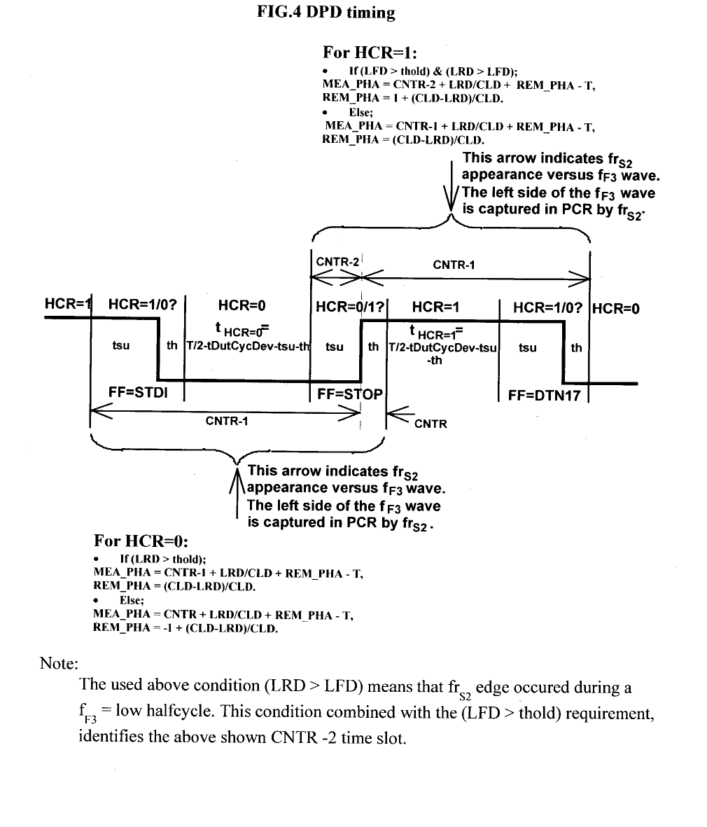

The first mentioned solution is introduced in the FIG. 1, and is explained further in the DESCRIPTION OF THE PREFERRED EMBODIMENT (see also FIG. 3 and FIG. 4).

The second mentioned solution can be implemented as it is explained below.

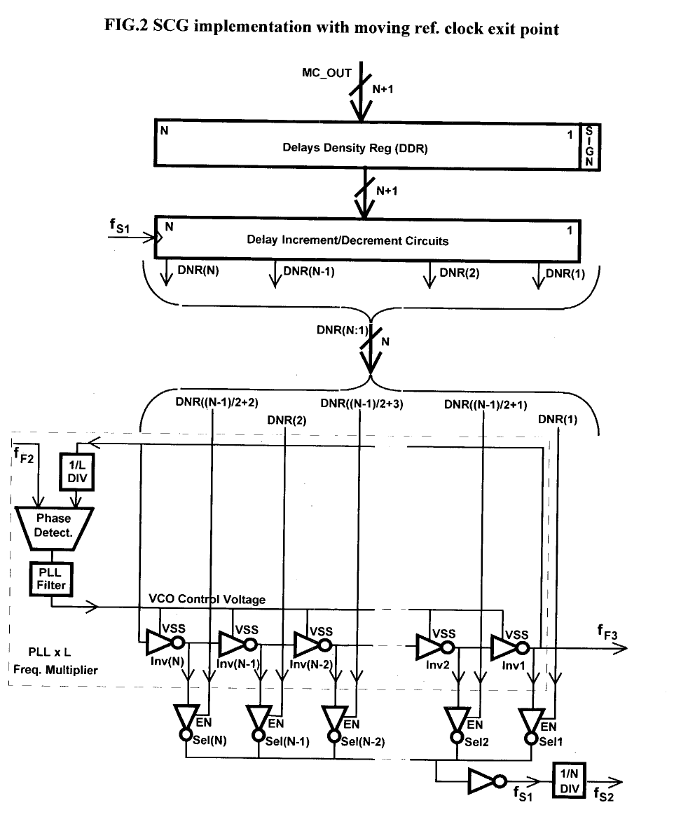

Instead of using the added propagation circuits (APC) from the FIG. 1; already existing in the system chain of inverters Inv(N) to Inv1 from the FIG. 2, can be utilized to measure positioning of a last fr_{S2} edge versus f_{F3} waveform by capturing the outputs of all the inverters Inv(N) to Inv1 in the phase capture register (PCR).

The second solution eliminates any need for delay calibration of the added propagation circuits (APC), because the replacing inverters Inv(N) to Inv1 have their delays controlled very accurately by the VCO Control Voltage.

### DESCRIPTION OF THE PREFERRED EMBODIMENT

Digital Phase Detector with Extended Resolution (DPD)

Digital phase detector with extended resolution (DPD) is described below, based on its presentation in FIG. 3 and FIG. 4.

Two major digital phase detector circuits are explained below.

A symmetrical twin pair PCBA/PCBB configuration allows higher counting speeds by eliminating all problems related to counters propagation delays.

The PCBA/PCBB configuration allows measurements of fr_{S2} versus f_{F3} phase errors, with a resolution of a single f period.

When an fr_{S2} rise signals the end of the current phase measurement in a currently active phase counter (PCBA or PCBB), counting of f_{F3} clock is inhibited and the phase counter content remains frozen, until the next rise of the fr_{S2} signal when the counted clock will be enabled again. The whole fr_{S2} cycle is a very long freeze period, which is more than sufficient to accommodate; any kind of counter propagation, and the counter transfer to a phase processing micro-controller, and the counter reset. During the freeze period a mate phase counter is kept enabled and provides measurement of fr_{S2}, phase.

Phase Capture Register (PCR) and its control and detection enhance phase detection resolution to a single inverter delay (i.e. by 10 times compared with conventional methods based on clock counting). This enhanced phase resolution is achieved by capturing f_{F3} propagation over inverters chain with a rising edge of fr_{S2}, in the PCR, which is later decoded and transferred to the micro-controller (MC).

More detailed operations of the PCBA/PCBB configuration for both alternatives STOPA=1 and STOPB=1, are explained below.

When STOPA signal is active, DPD circuits perform listed below functions.

PCBB counts all rising edges of f_{F3} clocks. PCBB generates SEL9 signal (when PCBB(9) goes high), which activates RD_REQ which initiates MC to read PCBA via CNTR(15:0).

MC calculates previous fr_{S2} versus f_{F3} phase error, by subtracting from the newly read

PCB, the number T of f_{F3} clocks which nominally should correspond to the frame fr_{S2} (as it is shown in the FIG. 4, T=N×P).

PCBB generates SEL 14 signal (when CTRB(14) goes high), which activates RST_PCBA which initiates PCBA reset circuits after its content has been read by MC.

When fr_{S2} rise occurs, STOP signal is activated and inverts STOPA/STOPB signals.

When STOPB signal is active all the above functionality is fulfilled with reversed roles of STOPB&PCBA versus STOPA&PCBB.

Detailed timing analysis of the enhanced phase capture circuits is shown in FIG. 4 and is explained below.

High Clock Region (HCR) signal shall be interpreted as it is defined below.

The HCR is set to 1: if f_{S2—}rise at fr_{F3}=high is detected by the STOP FF, after f_{F3—}fall at fr_{S2}=high was detected by the STDI FF (see FIG. 4). Therefore HCR=1 signals that fr_{S2} rising edge occurred in or around the f_{F3}=high halfcycle, as it is shown in the FIG. 4.

The HCR is reset to 0: if f_{F3—}rise at fr_{S2}=high is detected by the STOP FF, before f_{F3—}fall at fr_{S2}=high is detected by the STDI FF (see FIG. 4). Therefore HCR=0 signals that fr_{S2} rising edge occurred in or around the f_{F3}=low halfcycle; as it is shown in the FIG. 4.

PCR decoders are used for enhancing a phase detection resolution, and they are defined below.

Last Rise Decoder (LRD) provides a binary encoded position of f_{F3} rising edge, which has been captured at the most right location of the PCR.

Last Fall Decoder (LFD) provides a binary encoded position of f_{F3} falling edge, which has been captured at the most right location of the PCR.

Cycle Length Decoder (CLD) provides a binary encoded lengths of the f_{F3} wave, which has been captured between these 2 falling or 2 rising edges of the f_{F3} wave which occurred at the most right locations of the PCR.

Programmable micro-controller (MC) is used for processing DPD outputs, as it is described below.

MC algorithms for HCR, LRD, LFD and CLD interpretation are shown in FIG. 4, and use additional terms which are explained below.

Calculated by MC measured_phase (MEA PHA) represents an actual phase error between fr_{S2} versus the equivalent f frame; and consists of the listed below components.

CNTR-1/CNTR/CNTR-2 is an invalidated contents of a counter value CNTR which has been read by MC (all the invalidation algorithms are detailed in FIG. 4).

LRD/CLD is a normalized value of a phase error between fr_{S2} rise versus last f_{F3} rise, as it has been read by MC from the LRD and CLD decoders.

remaining_phase (REM_PHA) is calculated based on present measurement results, but MC stores and uses it to the correct next measurement result (all the REM_PHA calculation algorithms are shown in FIG. 4).

Since shown in the FIG. 4 component T, represents a normalized correct number of f_{F3} cycles per fr_{S2} period; the-T component transforms a captured number of f_{F3} cycles per fr_{S2} period, into a phase error between fr_{S2} versus the equivalent f_{F3} based frame.

It shall be noted that in most cases a first f_{F3} rise which occurs after fr_{S2} rise, will set STOP FF=1 and freeze the previously active counter by inverting STOPA/STOPB signals. Since the first f_{F3} rise will still add 1 to the previously active counter; MC shall subtract 1 from the counter it reads, while a newly activated mate counter will begin with a correct 0 value. Therefore the first component of a calculated by MC MEA_PHA shall be CNTR-1.

When fr_{S2} rise occurs during tₛᵤ of the STOP FF and HCR=1 (see the region “CNTR-2” in FIG. 4); the second f_{F3} rise will set STOP=1 and freeze previously active counter by inverting STOPA/STOPB signals. Since the first and the second f_{F3} rise will still add 1 to the previously active counter; MC shall subtract 2 from the counter it reads, while a newly activated mate counter will begin with an incorrect −1 value. Therefore the first component of a calculated by MC MEA_PHA shall be CNTR-2, and the first component of a stored by MC REM_PHA shall be +1.

When fr_{S2} rise occurs during tₕ of the STOP FF and HCR=0 (see the region “CNTR” in FIG. 4); the last passed f_{F3} rise has already set STOP=1 and has already frozen previously active counter by inverting STOPA/STOPB signals. Since the next f rise will not add 1 to the previously active counter; MC does not need to modify the counter it reads, while a newly activated mate counter will begin with an incorrect +1 value. Therefore the first component of a calculated by MC MEA_PHA shall be CNTR, and the first component of a stored by MC REM_PHA shall be −1.

While the LRD/CLD represents normalized PCR captured extension of the CNTR(15:0) captured phase, and is added to MEA_PHA; the remaining phase error between the fr_{S2} and the next f_{F3} rise, amounts to (CLD-LRD)/CLD and it is added to the REM_PHA in order to modify next measurement's MEA_PHA.

While the invention has been described with reference to particular example embodiments, further modifications and improvements which will occur to those skilled in the art, may be made within the purview of the appended claims, without departing from the scope of the invention in its broader aspect:

Numerous modification and variations of the present invention are possible in light of the above teachings. It is therefore to be understood that within the scope of the appended claims, the invention may be practiced otherwise than as specifically described herein.

What is claimed is:

1. A digital phase detector for providing an indication of a phase skew relationship between a first signal and a second signal, wherein a first signal clock is counted during every second signal frame.

2. A digital phase detector as claimed in claim 1, wherein: a nominal number of first signal clocks which corresponds to a zero phase skew between the first signal and the second signal, is subtracted from the counted number of the first signal clocks, in order to calculate a frame period skew.

3. A digital phase detector as claimed in claim 2, the digital phase detector comprising:
a first phase counter buffer for counting first signal clocks during every odd cycle of the second signal frame, and for buffering the counted clocks number during every following even cycle of the second signal frame;
a second phase counter buffer for counting first signal clocks during every even cycle of the second signal frame, and for buffering the counted clocks number during every following odd cycle of the second frame.

4. A digital phase detector as claimed in claim 3, wherein the digital phase detector comprises:
a phase detector control for controlling the counting and buffering functions of the first and second phase counter buffers.

5. A digital phase detector as claimed in claim 4, wherein said phase detector control further comprises:
detection of odd and even cycles of the phase counter buffers;
switching the counter buffers into the counting and buffering operations;
requesting a synchronizer control circuit to read the buffered count numbers;
resetting the buffers after their contents have been read by the control circuit.

6. A digital phase detector as claimed in claim 2, wherein:
said first clock counting is enabled by opening a logical gate which controls an application of the first clock to counter's clocking input;
said first clock counting is disabled by closing a logical gate which controls an application of the first clock to counter's clocking input.

7. A digital phase detector as claimed in claim 2, further comprising:
a phase capture register for capturing a state of outputs of serially connected gates which the first signal clock is propagated through, at the leading edge of the second signal frame.

8. A digital phase detector as claimed in claim 7, having additional further feature:
said serially connected logical gates which the first signal clock is propagated through, are an external propagation circuit which is primarily used for some other purposes and therefore it does not belong to the digital phase detector.

9. A digital phase detector as claimed in claim 8, using said external propagation circuit which is implemented as a ring oscillator which inverters are used as the serially connected gates which the first signal clock is propagated through.

10. A digital phase detector as claimed in claim 7, wherein the digital phase detector comprises:
said serially connected gates which the first signal clock is propagated through.

11. A digital phase detector as claimed in claim 5, wherein said phase detector control further comprises:
a stop flip-flop which is set to 1, whenever a rising edge of the first signal clock encounters for a first time a beginning of a new second signal frame.

12. A digital phase detector as claimed in claim 11, wherein said phase detector control further comprises:
a stop mate flip-flop which is reversed, whenever a falling edge of the first signal clock encounters for a first time a beginning of the stop flip-flop being set to 1.

13. A digital phase detector as claimed in claim 5, wherein said phase detector control further comprises:
a high clock region flip-flop which is set to 1, whenever a falling edge of the first signal clock encounters a beginning of a new second signal frame before a rising edge of the first signal clock encounters the beginning of the new second signal frame.

14. A digital phase detector as claimed in claim 7, wherein:
a contents of the phase capture register is used to calculate a phase skew difference between the last rise of the first signal clock and the beginning of a new second signal frame;
a contents of the phase capture register is used to calculate a remaining phase skew between the beginning of a new second signal frame and the first rise of the first signal clock;
the phase skew difference is added to the present measurement of a phase skew between the first signal and the second signal, wherein the present measurement applies to the present frame period of the second signal;
the remaining phase skew is added to the next measurement of a phase skew between the first signal and the second signal, wherein the next measurement applies to the next frame period of the second signal.

15. A digital phase detector as claimed in claim 14, wherein:
the remaining phase skew is calculated as equal to first signal clock period minus the phase skew difference.

16. A digital phase detector as claimed in claim 7, wherein:
a contents of the phase capture register is used to upgrade the counted number of first signal clocks to an actual number of first signal clocks which really occurred during the second signal frame.

17. A digital phase detector as claimed in claim 1, wherein the digital phase detector comprises:
a measurement of a phase skew difference between the last rise of the first signal clock and the beginning of a new second signal frame, which amounts to a fraction of a period of the first signal clock;
an addition of the phase skew difference to a number of the first signal clocks which have been counted for the present second signal frame;
calculation of a remaining phase skew as equal to first signal clock period minus the phase skew difference;
an addition of the remaining phase skew to a number of the first signal clocks which is counted for the next second signal frame;
